(19) United States
(12) Patent Application Publication
(10) Pub. No.: US 2013/0320356 A1
(43) Pub. Date: Dec. 5, 2013

(54) SEMICONDUCTOR STRUCTURE HAVING A NITRIDE ACTIVE LAYER ON A DOPED SILICON CARBIDE HEAT SPREADER

(71) Applicants: Abbas Torabi, North Andover, MA (US); Alan Bielunis, Hampstead, NH (US); Todd Southard, Tewksbury, MA (US)

(72) Inventors: Abbas Torabi, North Andover, MA (US); Alan Bielunis, Hampstead, NH (US); Todd Southard, Tewksbury, MA (US)

(73) Assignee: Raytheon Company, Waltham, MA (US)

(21) Appl. No.: 13/486,247

(22) Filed: Jun. 1, 2012

(51) Int. Cl. H01L 29/24

(52) U.S. Cl. 257/77; 257/E29.104

(57) ABSTRACT

A semiconductor structure having: a doped silicon carbide heat spreader; a semi-insulating silicon carbide layer disposed over the doped silicon carbide heat spreader; and a nitride (such as GaN, Indium nitride, Aluminum nitride) semiconductor layer disposed on the semi-insulating silicon carbide layer.

### TECHNICAL FIELD

This disclosure relates generally to semiconductor structure having a nitride active layer on a silicon carbide substrate and more particularly to such structures having improved heat removal properties and reduced cost.

### BACKGROUND AND SUMMARY

As is known in the art, high power, Gallium Nitride (GaN) transistors and microwave monolithically integrated Circuits (MMICs) are currently attached to a molybdenum or other metallic thermal conductors by soldering the chip in place. This assembly is then attached to a cooled stage via a conductive thermal epoxy. For GaN power amplifiers, the operating voltages and currents and hence power reach the limits of the thermal conductivity of the assemblage and hence if the heat generated within the RF portion of the device can't be removed effectively failures occur.

One such structure is shown in FIG. 1 to include a GaN MMIC grown on semi-insulating Silicon Carbide (SiC) attached to molybdenum tab (i.e., a narrow strip of thin metal) acting as the thermal heat spreader, which is placed on top of the base plate metal by an intervening thermal epoxy. Both top and bottom faces of the metallic heat spreader surfaces are facing a thermal resistor in the form of metallic solder and the thermal epoxy. The molybdenum metal itself has a low thermal conductivity and poor thermal mismatch to SiC.

The inventor has recognized that one principal reason for these failures is the thermal coefficient of expansion difference in material, from SiC substrate to molybdenum or other metal heat spreader interface. The inventor has further recognized that Silicon Carbide (4H—SiC;) has an in-plane lattice constant of 3.073 Å and a hexagonal crystalline structure, and thermal expansion coefficient (TEC) of 2.8337×10E-6/° C. in (0 0 01) plane, while molybdenum has an in plane lattice constant of 3.147 Å, with body centered cubic structure and thermal expansion coefficient of 4.98×10E-6/° C. at room temperature. Clearly the lattice constant difference, crystalline structure difference and the TEC differences are problematic during high temperature assembly and during the operation of the device.

In accordance with the disclosure, a semiconductor structure is provided comprising: a heat spreader having doped silicon carbide; a semi-insulating silicon carbide layer disposed over the doped silicon carbide; and a nitride semiconductor layer disposed on the a semi-insulating silicon carbide layer.

In one embodiment the heat spreader is a doped doped silicon carbide substrate;

In one embodiment the heat spreader is a doped doped silicon carbide layer;

In one embodiment, the semi-insulating layer is formed on the doped silicon carbide.

In one embodiment, the semi-insulating layer and the doped silicon carbide provide a unitary structure.

In one embodiment, the semi-insulating layer is an epitaxial layer disposed on the doped silicon carbide.

With such arrangements, the doped, highly electron rich SiC is used as a thermal spreader that has high thermal conductivity, modest electrical conductivity and is perfectly matched in thermal expansion coefficient to the semi-insulating silicon carbide upon which GaN Monolithic Microwave Integrated Circuits (MMICs) are formed. Such an approach will mitigate the many problems associated with metallic tabs used presently as thermal spreader in GaN on SiC power MMICs and circuitry by using a TEC matched thermal spreader in place of a metallic non TEC matched spreader.

In one embodiment, the doped silicon carbide is bonded to the semi-insulating SiC layer and associated MMIC with an electrically and thermally conductive bonding material.

The details of one or more embodiments of the disclosure are set forth in the accompanying drawings and the description below. Other features, objects, and advantages of the disclosure will be apparent from the description and drawings, and from the claims.

### DESCRIPTION OF DRAWINGS

FIG. 1 is a semiconductor MMIC according to the PRIOR ART;

FIG. 2 is a semiconductor MMIC structure according to the disclosure; and

FIG. 3 is a semiconductor structure according to another embodiment of the disclosure.

Like reference symbols in the various drawings indicate like elements.

### DETAILED DESCRIPTION

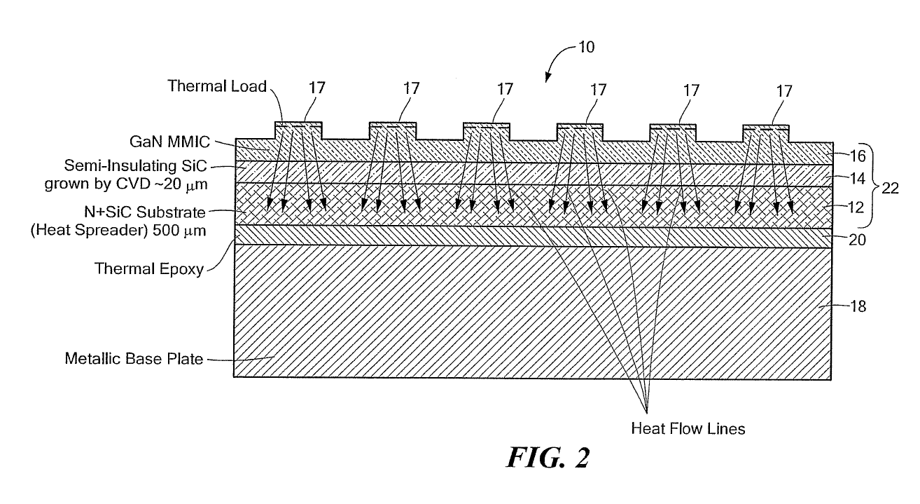

Referring now to FIG. 2, a semiconductor structure 10 is provided comprising: a heat spreader comprising a doped silicon carbide substrate 12; a semi-insulating silicon carbide layer 14 disposed over the doped silicon carbide substrate 12; and a nitride, such as, for example Gallium Nitride, (GaN), Indium nitride, Aluminum nitride, semiconductor layer 16 disposed on the semi-insulating layer 14. The semiconductor layer 16 has formed in the upper surface thereof active regions 17 where MMIC devices are formed. These MMIC devices generate heat that must be removed from the devices for proper operation and longevity of the circuits.

More particularly, the structure 10 includes an electrically and thermally conductive metal base plate 18, here for example, copper-molybdenum, which provides a heat sink through which the heat generated by the MMIC device is removed. Bonded to the base plate 18 by a thermally conductive epoxy 20 (such as EK1000 by Epoxy Technology, Inc., 14 Fortune Drive Billerica, Mass. 01821) is a unitary heat spreader structure 22 made up of the doped silicon carbide substrate 12 and the semi-insulating silicon carbide layer 14. More particularly, the substrate 12 is here, in one form N+ (4H or 6H) SiC having a thickness 300-500 um thick) for growth of layer 14, here for example, a thick layer of undoped SiC (approximately 20 um) by CVD, MOCVD or similar techniques and provides the heat spreader for the structure 10. For example, the silicon carbide substrate 12 is doped with Nitrogen having a doping concentration in the range of 1×10¹⁸ cm³ to 1×10²⁰ cm³.

This structure 22 is then used as a template identical to a semi-insulating SiC to grow the semiconductor layer 16 having then formed in layer 16 standard AlN/GaN/AlGaN HEMT or MMIC active devices. In this fashion the doped substrate 12 and free carriers therein are moved far enough from the active part of the device, that is the GaN channel, to minimize any RF losses in such active devices in layer 16. Such a structure 10 will allow RF operation of the GaN transistor in layer 16 without suffering from the microwave loss at X-band and higher frequencies.

Such a structure 10 provides an integrated approach to thermal spreader and GaN/AlGaN, which has several benefits:

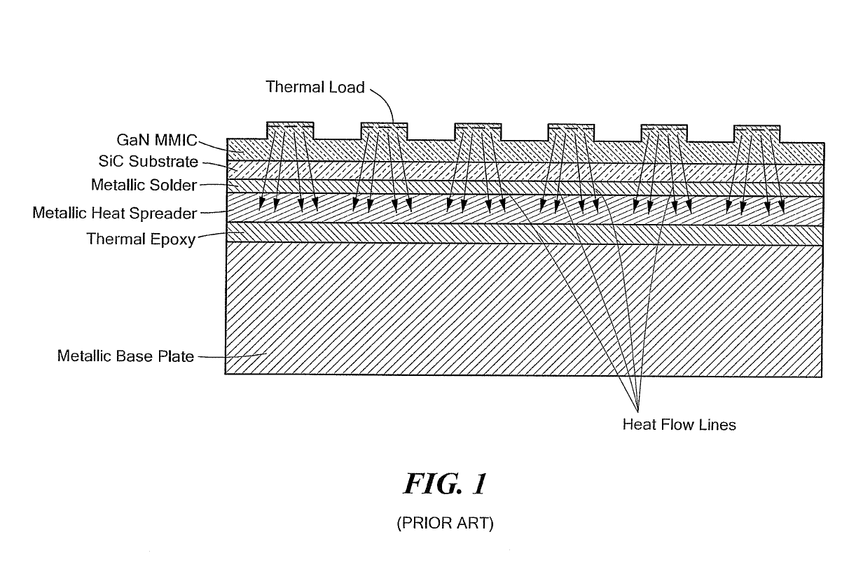

1. Removal of any interfacial layer between base SiC template and the heat spreader as in FIG. 1. Such an interfacial layer (e.g., molybdenum) in FIG. 1 creates unwanted and thermally resistive layer.

2. With TEC being perfectly matched from SiC layer 14 to n+ SiC substrate 12, there is zero residual strain and hence no device failure due to spreader, MMIC TEC mismatch.

3. The dollar cost of mounting the MMIC on molybdenum or other metallic tabs is removed.

4. The time required to do the assembly is eliminated.

5. The dollar cost of Semi-insulating SiC substrate (today's cost ˜$3000), is replaced with a much lower cost of doped conductive substrate (today's cost ˜$600) plus cost of SI—SiC growth.

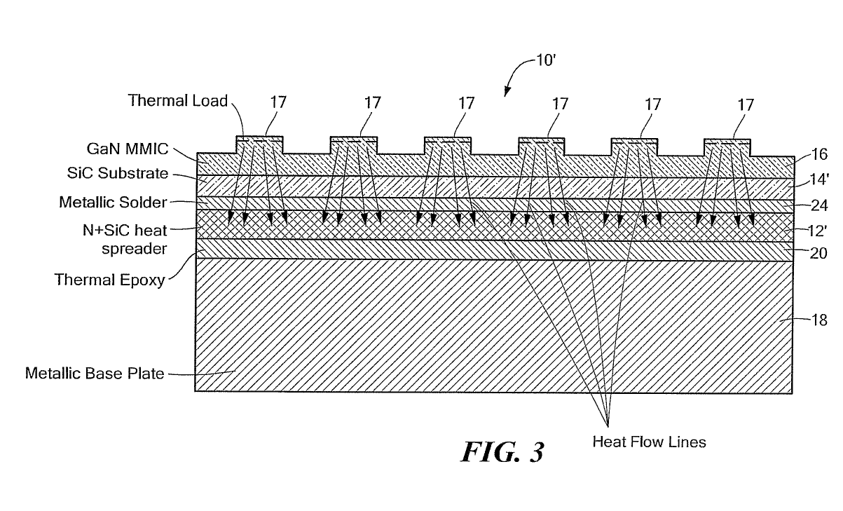

Referring now to FIG. 3, the semiconductor structure 10′ includes a N+ doped hexagonal (4H or 6H) SiC (300-500 um thick) heat spreader layer 12′ used as a stand-alone heat spreader 12′ directly replacing the existing metal (e.g., molybdenum) based heat spreader of FIG. 1. Here, the heat spreader is a N+ doped SiC layer 12′, here having a thickness in the range of 300-500 um, which is metalized on top and bottom surfaces with thin metallic films, such as for example, nickel/gold (not shown) having a thickness in the range of 0.1 to 10 um. The bottom surface is bonded to the metallic heat plate 18 by a thermally conductive epoxy 20 (such as EK1000 by Epoxy Technology, Inc., 14 Fortune Drive Billerica, Mass. 01821). The GaN MMIC structure layers 16 with regions 17 therein are formed on a semi-insulating SiC substrate 14′ as shown. The semi-insulating SiC substrate 14′ is soldered, here with a thermally and electrically conductive solder 24 such as Au/Sn, to the doped SiC substrate 12′ heat spreader. This implementation of the invention has several benefits:

1. TEC mismatch between semiconductor and heat spreader is eliminated.

2. Thermal conductivity is enhanced over that of traditional Molybdenum heat spreaders

3. The electrical conductivity of N+ SiC 12′ is high enough, for most applications, to allow simplified plating (top & bottom only) of the heat spreader 12′ reducing cost and allowing fabrication using standard wafer level processing techniques.

4. The dollar cost of doped conductive SiC substrate 12′ (today's cost ˜$600 for 100 mm wafer) provides heat spreaders less expensive than similar sized molybdenum spreaders

A number of embodiments of the disclosure have been described. Nevertheless, it will be understood that various modifications may be made without departing from the spirit and scope of the disclosure. Accordingly, other embodiments are within the scope of the following claims.

What is claimed is:

1. A semiconductor structure, comprising
a heat spreader comprising doped silicon carbide;
a semi-insulating silicon carbide layer disposed over the doped silicon carbide heat spreader;
a nitride semiconductor layer disposed on the semi-insulating silicon carbide layer.

2. The semiconductor structure recited in claim 1 wherein the semi-insulating layer is formed on the doped silicon carbide heat spreader e.

3. The semiconductor structure recited in claim 2 wherein the semi-insulating layer and the doped silicon carbide heat spreader provide a unitary structure.

4. The semiconductor structure recited in claim 2 wherein the semi-insulating layer is an epitaxial layer disposed on the doped silicon carbide heat spreader.

5. The semiconductor structure recited in claim 1 wherein the doped silicon carbide heat spreader is bonded to the semi-insulating layer with an electrically conductive bonding material.

6. The structure recited in claim 1 wherein the nitride is gallium nitride, Indium nitride, or Aluminum nitride.

7. The structure recited in claim 1 wherein the nitride is gallium nitride

8. The structure recited in claim 6 wherein the semi-insulating layer is formed on the doped silicon carbide heat spreader.

9. The semiconductor structure recited in claim 7 wherein the semi-insulating layer and the doped silicon carbide heat spreader provide a unitary structure.

10. The semiconductor structure recited in claim 7 wherein the semi-insulating layer is an epitaxial layer disposed on the doped silicon carbide heat spreader.

11. The semiconductor structure recited in claim 6 wherein the doped silicon carbide heat spreader is bonded to the semi-insulating layer with an electrically conductive bonding material.

12. The structure recited in claim 7 wherein the semi-insulating layer is formed on the doped silicon carbide heat spreader.

13. The semiconductor structure recited in claim 11 wherein the semi-insulating layer and the doped silicon carbide heat spreader provide a unitary structure.

14. The semiconductor structure recited in claim 11 wherein the semi-insulating layer is an epitaxial layer disposed on the doped silicon carbide heat spreader.

15. The semiconductor structure recited in claim 7 wherein the doped silicon carbide heat spreader is bonded to the semi-insulating layer with an electrically conductive bonding material.

16. The semiconductor structure recited in claim 1 wherein the doped silicon carbide heat spreader is a substrate.

17. The semiconductor structure recited in claim 1 wherein the doped silicon carbide heat spreader is a layer of silicon carbide.
